(19) United States
(12) Patent Application Publication
(10) Pub. No.: US 2023/0037217 A1
(43) Pub. Date: Feb. 2, 2023

(54) BATTERY INTERNAL SHORT CIRCUIT DETECTION AND MITIGATION

(71) Applicant: Ford Global Technologies, LLC, Dearborn, MI (US)

(72) Inventors: Di Zhu, Canton, MI (US); Benjamin A. Tabatowski-Bush, Ann Arbor, MI (US)

(21) Appl. No.: 17/387,206

(22) Filed: Jul. 28, 2021

(51) Int. Cl. B60L 3/00; B60L 58/18; G01R 31/382; H01M 10/48; G01R 19/165; H02J 7/00; G01R 31/52

(52) U.S. Cl. CPC B60L 3/0046; B60L 58/18; G01R 31/382; H01M 10/482; G01R 19/16542; H02J 7/0029; G01R 31/52

(57) ABSTRACT

A controller selectively prevents electrical power flow from a traction battery to an electric machine based on an actual rate of charge acquired by a cell of the traction battery per unit of actual increase in amp hours and an expected rate of charge acquired per unit of expected increase in amp hours.

### TECHNICAL FIELD

This disclosure relates to the control of automotive batteries and electrified powertrains.

### BACKGROUND

An alternatively powered vehicle may include a traction battery arranged to provide power to an electric machine. The electric machine may transform electrical energy from the traction battery to mechanical energy to move wheels of the vehicle. The electric machine may also transform mechanical energy from the wheels to electrical energy for storage in the traction battery.

### SUMMARY

A vehicle includes an electric machine, a traction battery arrangement, and a controller. The controller, responsive to a difference being greater than a threshold value, prevents the traction battery arrangement from powering the electric machine. The difference is between an actual voltage change per actual amp hours change over a predetermined time for a cell of the traction battery arrangement and an expected voltage change per expected amp hours change over the predetermined time.

A method includes preventing at least one contactor electrically between a traction battery arrangement and electric machine from closing to prevent electrical power flow from the traction battery arrangement to the electric machine after a difference between an actual voltage change per actual amp hours change over a predetermined time for a cell of the traction battery arrangement and an expected voltage change per expected amp hours change over the predetermined time exceeds a threshold value.

A powertrain includes an electric machine and a controller. The controller selectively prevents electrical power flow from a traction battery to the electric machine based on an actual rate of charge acquired by a cell of the traction battery per unit of actual increase in amp hours and an expected rate of charge acquired per unit of expected increase in amp hours.

### BRIEF DESCRIPTION OF THE DRAWINGS

FIG. 1 is a schematic diagram of a battery cell equivalent circuit with an internal short circuit resistance.

FIG. 2 is a plot of cell voltage versus time for cells with and without an internal short circuit resistance.

FIG. 3 is a plot of Et_pred and Et_calc for a cell without an internal short circuit resistance.

FIG. 4 is a plot of Et_pred and Et_calc for a cell with an internal short circuit resistance.

FIG. 5 is a block diagram of a battery system.

FIG. 6 is a flow chart of an algorithm for controlling an electrified powertrain.

FIG. 7 is a block diagram of an automotive vehicle.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

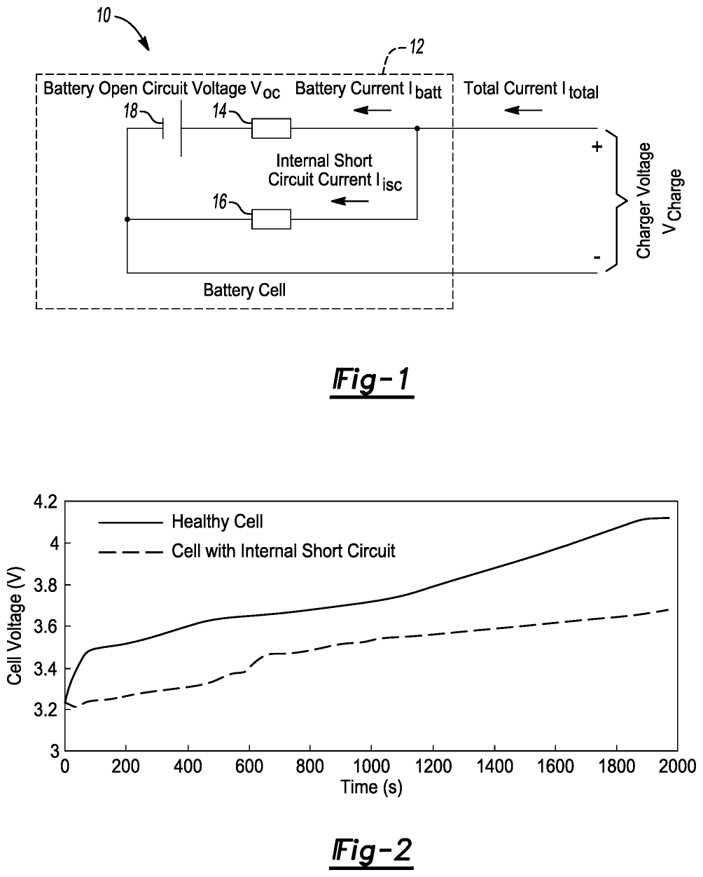

An interesting area of research relates to the detection of battery internal short circuit resistances, which may have many causes. One of the causes is copper dissolution. Dissolved copper grows through the separator and eventually creates a short circuit between the anode and cathode. FIG. 1 illustrates an equivalent circuit 10 of a battery cell 12 with a battery internal resistance 14, an internal short circuit resistance 16, and a battery open circuit voltage 18. The total current Itotal is the sum of the battery current Ibatt and the internal short circuit current Iisc. A possible scenario occurs when the battery 12 is getting charged. Energy is pushed into the cell with the internal short circuit resistance 16 while the internal short circuit resistance 16 is converting the electrical energy into heat. If not detected early, the cell with the internal short circuit resistance may experience thermal issues.

Detection of an internal short circuit resistance can be difficult because the cell with the internal short circuit resistance does not show a large voltage deviation as illustrated in FIG. 2. The solid line curve denotes the voltage profile of a healthy cell. The dashed line curve represents the voltage profile of a cell with an internal short circuit resistance. Both cells are charged under the same conditions. The voltage of the cell with the internal short circuit resistance, however, increases more slowly than the voltage of the healthy cell. This is due to some of the energy being converted into heat by the internal short circuit resistance.

Voltage-based detections are widely used for a variety of fault detections. In one example, the voltage threshold for detecting cell voltage deviation is 0.715V, which may be ineffective for identifying an internal short circuit resistance. The voltage threshold cannot be tuned to a smaller number (e.g., 0.25V or less) because that will result in false positive results. In addition, even if existing methods detected the voltage deviation, it may not take effective action to prevent thermal issues from occurring. Instead, it may trigger a message indicating a voltage deviation condition. For other faults, this level of action is sufficient. Generating a message, however, may not be sufficient to prevent thermal issues during charging.

The inventors have recognized that the problems described above may be addressed by apparatuses and methods that utilize model predictive control to detect presence of internal short circuit resistances. The proposed techniques take advantage of a characteristic parameter (i.e., the rate of accumulated voltage change divided by the accumulated amp hour increase at time t). The equation to calculate the rate Et_calc is listed below:

Et_calc=(Vt−V0)/(Ct−C0) (1)

where Vt, V0, Ct, and C0 denote the cell voltages and the accumulated amp hour increase at times t and 0, respectively. This rate indicates how much the cell voltage changes for a given change of amp hour value. When a cell with an internal short circuit resistance is charged, its Et_calc has a different profile than a healthy cell.

Regarding the model predictive control, a deep neural network (e.g., long short term memory, autoencoder, etc.) is built to predict the rate of healthy cells Et_pred. Et_pred represents the predicted rate of the accumulated voltage change divided by the accumulated amp hour increase at time t. Since the neural network is trained using data from cells that do not have internal short circuit resistances, the difference between the predicted rate Et_pred and the calculated rate Et_calc using (1) is relatively small as shown in FIG. 3.

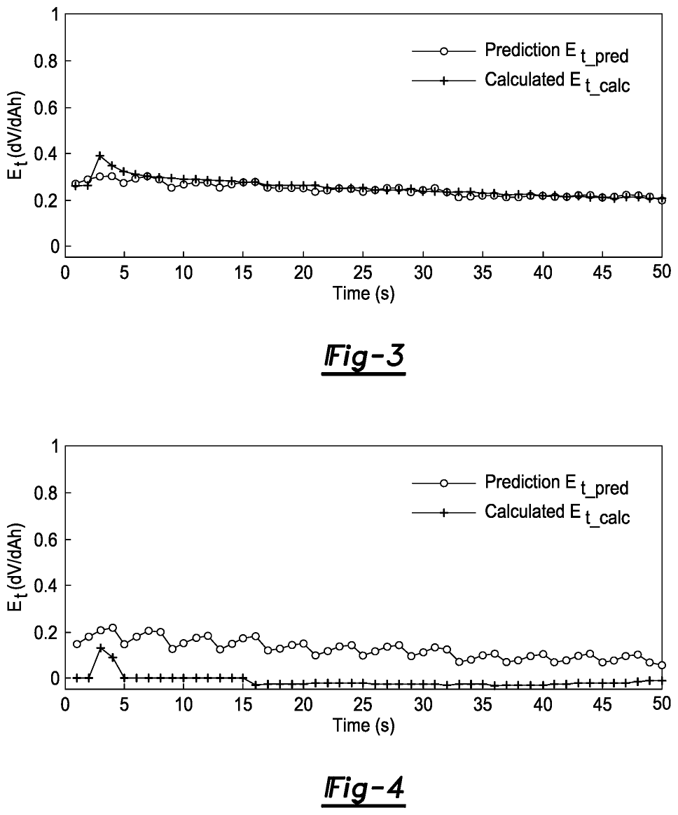

When data from a cell that has an internal short circuit resistance is fed into the neural network however, the difference between Et_pred and Et_calc becomes significant as illustrated in FIG. 4. This is because the neural network is only trained using data from the healthy cells. If the profile of Et_pred does not match the profile of Et_calc, presence of an internal short circuit condition is detected.

To ensure the robustness of this method, a threshold Te and a counter threshold Tc may also be used. The thresholds Te and Tc can be set for example to 0.1 V/Ah and 3, respectively. When the difference between Et_pred and Et_calc is greater than 0.1, the counter increments 1. Once the counter reaches 3, an internal short circuit resistance condition is declared.

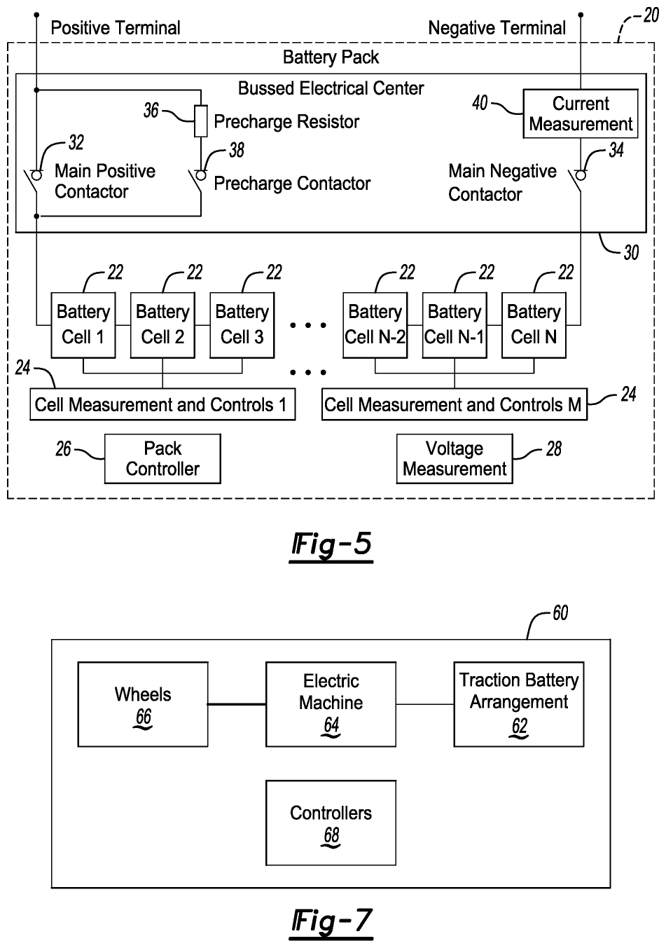

Referring to FIG. 5, a battery pack 20 includes N cells 22, M cell measurement and control boards 24, a pack controller 26, a voltage measurement 28, and a bussed electrical center 30. The bussed electrical center 30 includes main positive and main negative contactors 32, 34, a series connected pre-charge resistor 36 and pre-charge contactor 38 in parallel with the main positive contactor 32, and a current measurement 40. The current measurement 40 (e.g., current sensor) provides current data to the pack controller 26 for the amp hour counting during the charge event. The cell measurement and control boards 24 (e.g., voltage sensors, etc.) provide cell voltages to the pack controller 26 so the rate of accumulated voltage change divided by the accumulated amp hour increase at time t can be calculated in real time. In addition, the measured current, cell voltages, and accumulated amp hour values are inputs fed into a pre-built neural network. Based on the inputs, the trained neural network predicts the rate Et_pred in real time.

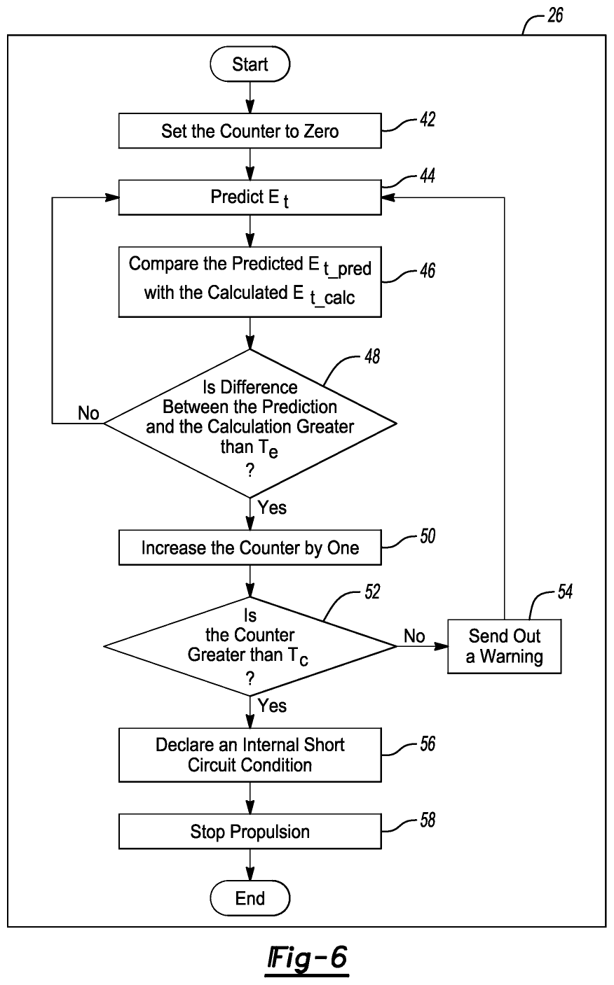

Referring to FIG. 6, the process starts with setting the counter to 0 at operation 42. After that, the pre-trained neural network predicts the rate Et_pred at time t at operation 44. Once Et_pred becomes available, Et_pred is compared with the calculated rate Et_calc at operation 46. Et_calc is calculated by the pack controller 26 based on the amp hour counting result and the measured cell voltage. If at operation 48 the difference between Et_pred and Et_calc is greater than the threshold Te, the counter increments 1 at operation 50. Otherwise, the pack controller 26 begins the prediction for the next time step, then returning to operation 44. If at operation 52 the counter is less than or equal to the threshold Tc, a warning message is sent out at operation 54 indicating the initial detection result, then returning to operation 44. Once the counter exceeds the threshold Tc (e.g., 3), an internal short circuit resistance is confirmed and the pack controller 26 declares an internal short circuit condition at operation 56. After that, the battery pack 20 is prevented from supporting propulsion at operation 58.

Referring to FIG. 7, an automotive vehicle 60 includes a traction battery arrangement 62 (including the battery pack 20), an electric machine 64, wheels 66, and one or more controllers 68 (including in some arrangements the pack controller 26). The one or more controllers 68 are in communication with and exert control over the traction battery arrangement 62 and electric machine 64. The electric machine 64 is arranged to convert electrical power from the traction battery arrangement 62 to mechanical power to propel the wheels 66. The electric machine 64 is also arranged to convert mechanical power from the wheels 66, during for example a regenerative braking event, to electrical power for storage in the traction battery arrangement 62. Responsive to presence of the conditions described in operation 56 (FIG. 6), the one or more controllers 66 may command at least one of the main positive and main negative contactors of the traction battery arrangement to open to prevent the traction battery arrangement 62 from supporting propulsion of the wheels 66 by the electric machine 62 as mentioned in operation 58 (FIG. 6).

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. With reference to FIG. 6 for example, counters need not be used to implement the strategy described. Other scenarios are also possible. The words used in the specification are words of description rather than limitation, and it is understood that various changes may be made without departing from the spirit and scope of the disclosure.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A vehicle comprising:
an electric machine;
a traction battery arrangement; and
a controller programmed to, responsive to a difference being greater than a threshold value, prevent the traction battery arrangement from powering the electric machine, wherein the difference is between (i) an actual voltage change per actual amp hours change over a predetermined time for a cell of the traction battery arrangement and (ii) an expected voltage change per expected amp hours change over the predetermined time.

2. The vehicle of claim 1, wherein the controller is further programmed to implement a deep neural network that generates the expected voltage change per expected amp hours change over the predetermined time.

3. The vehicle of claim 2, wherein the deep neural network is a long short term memory.

4. The vehicle of claim 1, wherein preventing the traction battery arrangement from powering the electric machine includes opening at least one contactor of the traction battery arrangement.

5. The vehicle of claim 1, wherein the controller is further programmed to, responsive to the difference being greater than the threshold value, increment a counter.

6. The vehicle of claim 1, wherein the controller is further programmed to, responsive to the difference being greater than the threshold value, generate a message indicating presence of the difference.

7. A method comprising:
preventing at least one contactor electrically between a traction battery arrangement and electric machine from closing to prevent electrical power flow from the traction battery arrangement to the electric machine after a difference between an actual voltage change per actual amp hours change over a predetermined time for a cell of the traction battery arrangement and an expected voltage change per expected amp hours change over the predetermined time exceeds a threshold value.

8. The method of claim 7 further comprising generating the expected voltage change per expected amp hours change over the predetermined time via a deep neural network.

9. The method of claim 8, wherein the deep neural network is a long short term memory.

10. The method of claim 7 further comprising incrementing a counter after the difference exceeds the threshold value.

11. The method of claim 7 further comprising generating a message indicating presence of the difference after the difference exceeds the threshold value.

12. A powertrain comprising:
an electric machine; and
a controller programmed to selectively prevent electrical power flow from a traction battery to the electric machine based on an actual rate of charge acquired by a cell of the traction battery per unit of actual increase in amp hours and an expected rate of charge acquired per unit of expected increase in amp hours.

13. The powertrain of claim 12, wherein the controller is further programmed to implement a deep neural network that generates the expected rate of charge acquired per unit of expected increase in amp hour.

14. The powertrain of claim 13, wherein the deep neural network is a long short term memory.

15. The powertrain of claim 12, wherein selectively preventing power flow from the traction battery to the electric machine includes selectively opening at least one contactor of the traction battery arrangement.

16. The powertrain of claim 12, wherein the actual rate of charge acquired by a cell of the traction battery per unit of actual increase in amp hours is defined as the quotient of a change in voltage of the cell and a change in amp hours of the cell
